(19) United States
(12) Patent Application Publication
(10) Pub. No.: US 2024/0254372 A1
(43) Pub. Date: Aug. 1, 2024

(54) ADHESIVE COMPOSITION FOR SEMICONDUCTOR PROCESSING, FILM COMPRISING SAME FOR SEMICONDUCTOR PROCESSING, AND METHOD FOR PRODUCING SEMICONDUCTOR PACKAGE USING SAME

(71) Applicant: LG CHEM, LTD., Seoul (KR)

(72) Inventors: Hee SONG, Daejeon (KR); Ji Ho HAN, Daejeon (KR); Kwang Joo LEE, Daejeon (KR)

(21) Appl. No.: 18/290,527

(22) PCT Filed: Jul. 29, 2022
(86) PCT No.: PCT/KR2022/011220

§ 371 Date: Nov. 14, 2023

(30) Foreign Application Priority Data
Jan. 26, 2022 (KR) 10-2022-0011247

(51) Int. Cl. C09J 11/06; C08K 5/315; C08K 5/3492; C09J 7/30; C09J 133/10; H01L 21/683

(52) U.S. Cl. CPC C09J 11/06; C09J 7/30; C09J 133/10; H01L 21/6836; C08K 5/315; C08K 5/3492; C09J 2301/408; C09J 2433/00

(57) ABSTRACT

An adhesive composition for a semiconductor process, a film for a semiconductor process comprising the same, and a method for manufacturing a semiconductor package using the same are provided. The adhesive composition provides the film for a semiconductor process having excellent adhesion reliability to a wafer even during a process of debonding a carrier from the wafer.

### CROSS-REFERENCE TO RELATED APPLICATION

This application is a US national phase of international application No. PCT/KR2022/011220 filed on Jul. 29, 2022, and claims priority to and the benefit of Korean Patent Application No. 10-2022-0011247 filed on Jan. 26, 2022, the contents of which are hereby incorporated by reference in their entirety.

### FIELD OF DISCLOSURE

The present disclosure relates to an adhesive composition for a semiconductor process, a film for a semiconductor process including the same, and a method for manufacturing a semiconductor package using the same.

### BACKGROUND

In general, a process of manufacturing a semiconductor chip includes a process of forming fine patterns on a wafer, and a process of packaging the wafer by polishing it to meet the specifications of a final device.

In these days, as semiconductor package technology has been improved in performance, the degree of integration of semiconductors is increasing, and the thickness of a wafer is becoming ultra-thin. Therefore, to facilitate the handling of the wafer during the process, a carrier is temporarily employed and attached to the wafer, and after the completion of handling the wafer, a debonding process of delaminating the carrier is performed.

The debonding process of the carrier employs a heat treatment method and a laser irradiation method. In particular, the process of debonding the carrier using an excimer laser has an advantage that enables the processing to be performed very quickly in a selective region.

However, it has drawbacks in that the excimer laser output may be high, and a PET film, a PEN film, a PO film, and the like, which are substrates of most films for a semiconductor process, may be deformed or damaged by the excimer laser. As a result, the damage caused on the substrate of the film for a semiconductor process by the excimer laser during the carrier debonding process may lead to the breakage of the film for a semiconductor process or looseness in an adhesive layer, which may in turn decrease the wafer attachment reliability and generate problems in the wafer processing process.

Accordingly, there is a need for a technology capable of developing a film for a semiconductor process exhibiting excellent adhesion reliability to a wafer even during the carrier debonding process employing an excimer laser.

### SUMMARY

The present disclosure is to provide an adhesive composition for a semiconductor process capable of providing a film for a semiconductor process having excellent reliability of adhesion to a wafer even during a process of debonding a carrier from the wafer, a film for a semiconductor process including the same, and a method for manufacturing a semiconductor package using the same.

However, the objectives to be addressed by the present disclosure are not limited to the above-mentioned problems, and other problems not mentioned will be clearly appreciated by those skilled in the art from the following description.

An embodiment of the present disclosure provides an adhesive composition for a semiconductor process, the adhesive composition comprising an adhesive binder resin; a photoinitiator; and a laser absorber, wherein the laser absorber absorbs a laser having a wavelength in the range of 250 nm to 350 nm, and the photoinitiator is activated by a light having a wavelength different from that of the laser.

Additionally, an embodiment of the present disclosure provides a film for a semiconductor process, the film including a substrate; and an adhesive layer having said adhesive composition for a semiconductor process.

Also, an embodiment of the present disclosure provides a method for manufacturing a semiconductor package, the method comprising: preparing a wafer stack comprising a wafer and a carrier provided on one surface of the wafer; attaching the adhesive layer of the film for a semiconductor process on the other surface of the wafer; delaminating the carrier from the one surface of the wafer by irradiating a laser to the wafer stack; processing the wafer; and delaminating the film for a semiconductor process from the other surface of the wafer after curing the adhesive layer by irradiating a light on the adhesive layer.

The adhesive composition for a semiconductor process according to an embodiment of the present disclosure enables easy implementation of an adhesive layer that effectively absorbs the laser and effectively reduces its adhesion after being irradiated with the light.

The film for a semiconductor process according to an embodiment of the present disclosure effectively absorbs the laser irradiated during the debonding process of the wafer carrier, and effectively reduces its adhesion after the light irradiation, so that it can be easily delaminated from the wafer.

The method for manufacturing a semiconductor package according to an embodiment of the present disclosure enables the carrier to be easily delaminated using an excimer laser after processing a wafer, and enables the film for a semiconductor process to be effectively delaminated through light irradiation, thereby effectively improving the semiconductor package manufacture efficiency.

Effects of the present disclosure are not limited to the above-described effects, but other effects not described above will be clearly appreciated by those skilled in the art from the present specification and accompanying drawings.

### BRIEF DESCRIPTION OF DRAWING

FIG. 1 is a diagram schematically showing a method for manufacturing a semiconductor package according to an embodiment of the present disclosure.

### DETAILED DESCRIPTION

Throughout this specification, when a part “includes” or “comprises” a component, it means not that the part excludes other component, but instead that the part may further include other component unless expressly stated to the contrary.

Throughout the specification, when a member is described as being located “on” another member, this includes not only a case in which the member is in contact with the other member but also a case in which another member exists between the two members.

Throughout this specification, the unit “parts by weight” may mean a ratio of weight between the respective components.

Throughout this specification, “(meth) acrylate” is used to collectively refer to acrylate and methacrylate.

Throughout this specification, terms including an ordinal number such as “first” and “second” are used for the purpose of distinguishing one component from another component, and these components are not limited by the ordinal numbers. For example, without departing from the right scope of the present disclosure, a first component may be termed as a second component, and similarly, a second component may be termed as a first component.

Hereinafter, the present specification will be described in more detail.

An embodiment of the present disclosure provides an adhesive composition for a semiconductor process, the composition comprising an adhesive binder resin; a photoinitiator; and a laser absorber, wherein the laser absorber absorbs a laser having a wavelength in the range of 250 nm to 350 nm, and the photoinitiator is activated by a light having a wavelength different from that of the laser.

The adhesive composition for a semiconductor process according to an embodiment of the present disclosure enables easy implementation of an adhesive layer that effectively absorbs the laser and effectively reduce its adhesion after being irradiated with the light.

Specifically, the composition for a semiconductor process can effectively absorb an excimer laser irradiated for debonding (delamination) of a semiconductor carrier in a method of manufacturing a semiconductor package to be described later. Through this, it is possible to effectively prevent the excimer laser from reaching the substrate of the film for a semiconductor process to be described later. Therefore, it is possible to prevent the substrate for a semiconductor process from being damaged or deformed by the excimer laser, thereby further improving the adhesion reliability of the film for a semiconductor process to the wafer. In addition, the composition for a semiconductor process may be cured by being irradiated with the light having a wavelength different from that of the laser, thereby effectively reducing its adhesion. After debonding the wafer carrier, by irradiating light to the film for a semiconductor process, the adhesion of the adhesive layer including the composition for a semiconductor process can be effectively reduced. Through this, the film for a semiconductor process may be effectively debonded from the wafer.

According to an embodiment of the present disclosure, the wavelength range of the laser absorbed by the laser absorber may be 250 nm to 350 nm, 270 nm to 330 nm, 290 nm to 310 nm, or 300 nm to 320 nm. The laser may have a wavelength in the aforementioned wavelength range.

According to an embodiment of the present disclosure, the laser absorber may absorb an excimer laser having a wavelength of 300 nm to 320 nm. Specifically, the laser absorber may absorb the excimer laser, and the wavelength range of the excimer laser that the laser absorber absorbs may be 305 nm to 315 nm, 300 nm to 320 nm, or 310 nm to 320 nm. With the excimer laser having the above-described wavelength range, a process of debonding a carrier from a wafer can be effectively performed in a method for manufacturing a semiconductor package to be described later. Accordingly, the laser absorber included in the adhesive composition for a semiconductor process can effectively absorb the excimer laser having the aforementioned wavelength range.

According to an embodiment of the present disclosure, the laser absorber may include at least one of a triazine-based compound and a cyanoacrylate-based compound. That is, the laser absorber may include at least one of a laser absorber containing a triazine-based compound or a laser absorber containing a cyanoacrylate-based compound. The laser absorber including the above-mentioned compound can effectively absorb the excimer laser having the above-mentioned wavelength range. Additionally, the adhesive composition for a semiconductor process including the laser absorber does not significantly change its optical transmittance even at the time of heat treatment at an elevated temperature (e.g., 240° C.), so it can be easily applied to a semiconductor package manufacturing process.

On the other hand, when using a laser absorber including a benzoate-based compound, a benzotriazole-based compound, or an oxanilide-based compound, it may be difficult to effectively absorb the excimer laser, and the optical transmittance may be greatly changed at the time of the heat treatment at an elevated temperature, so it may be difficult to apply such laser absorber to a semiconductor package manufacturing process.

According to an embodiment of the present disclosure, the triazine-based compound included in the laser absorber may include at least one selected from the group consisting of 2-(4,6-diphenyl-1,3,5-triazin-2-yl)-5-[2-(2-ethylhexanoyloxy)ethoxy]-phenol (AD K STAB LA46, manufactured by ADEKA), 2-hydroxyphenyl-s-triazine derivative (Tinuvin 1600, manufactured by BASF), 2,4-bis-[{4-(4-ethylhexyloxy)-4-hydroxy}-phenyl]-6-(4-methoxyphenyl)-1,3,5-triazine (Tinosorb S, manufactured by BASF), 2,4-bis[2-hydroxy-4-butoxyphenyl]-6-(2,4-dibutoxyphenyl)-1,3,5-triazine (TINUVIN 460, manufactured by BASF), a reaction product (TINUVIN 400, manufactured by BASF) of 2-(4,6-bis(2,4-dimethylphenyl)-1,3,5-triazin-2-yl)-5-hydroxyphenyl and [(C10-C16 (mainly C12-C13)alkyloxy)methyl]oxirane, 2-[4,6-bis(2,4-dimethylphenyl)-1,3,5-triazin-2-yl]-5-[3-(dodecyloxy)-2-hydroxy propoxy]phenol, a reaction product (TINUVIN 405, manufactured by BASF) of 2-(2,4-dihydroxyphenyl)-4,6-bis-(2,4-dimethylphenyl)-1,3,5-triazine and (2-ethylhexyl)-glycidic acid ester, 2-(4,6-diphenyl-1,3,5-triazin-2-yl)-5-[(hexyl)oxy]-phenol (TINUVIN 1577, manufactured by BASF), and 2-(2-hydroxy-4-[1-octyloxycarbonylethoxy]phenyl)-4,6-bis(4-phenylphenyl)-1,3,5-triazine (TINUVIN 479, manufactured by BASF).

Additionally, the cyanoacrylate-based compound included in the laser absorber may include at least one selected from the group consisting of 1,3-bis-((2′-cyano-3′,3′-diphenylacryloyl)oxy)2,2-bis-(((2′-cyano-3′,3′-diphenylacryloyl)oxy)methyl)-propane (Uvinul 3030, manufactured by BASF), alkyl-2-cyanoacrylate, cycloalkyl-2-cyanoacrylate, alkoxyalkyl-2-cyanoacrylate, alkenyl-2-cyanoacrylate, and alkynyl-2-cyanoacrylate.

According to an embodiment of the present disclosure, the content of the laser absorber may be 0.5 parts by weight or more and 3 parts by weight or less with respect to 100 parts by weight of the adhesive binder resin. Specifically, with respect to 100 parts by weight of the adhesive binder resin, the content of the laser absorber may be 0.7 parts by weight or more and 2.7 parts by weight or less, 0.9 parts by weight or more and 2.3 parts by weight or less, 1 part by weight or more and 2 parts by weight or less, 0.5 parts by weight or more and 1.5 parts by weight or less, or 1 part by weight or more and 2.5 parts by weight or less. When the content of the laser absorber included in the adhesive composition for a semiconductor process is within the above-described range, the adhesive composition for a semiconductor process can effectively absorb an excimer laser, and its optical transmittance is not significantly changed even at the time of high-temperature heat treatment, so it can be easily applied to a package manufacturing process.

According to an embodiment of the present disclosure, the adhesive composition for a semiconductor process may include a photoinitiator. Any photoinitiator used in the art may be employed as the photoinitiator without limitation. Specifically, the photoinitiator may include at least one of a benzophenone-based photoinitiator, an acetophenone-based photoinitiator, a ketal-based photoinitiator, and a thioxanthone-based photoinitiator. At least one of Irgacure #819 (IGM Resins Company), Omnirad 907 (IGM Resins Company), HP-8 (Miwon Specialty Company), Irgacure #651 (BASF Company), Irgacure #184 (BASF Company), Irgacure #1173 (BASF Company) and CP-4 (Irgacure #184) may be used as the photoinitiator without being limited thereto.

According to an embodiment of the present disclosure, with respect to 100 parts by weight of the adhesive binder resin, the content of the photoinitiator may be 1 part by weight or more and 5 parts by weight or less. Specifically, with respect to 100 parts by weight of the adhesive binder resin, the content of the photoinitiator may be 1.3 parts by weight or more and 4.5 parts by weight or less, 1.5 parts by weight or more and 4 parts by weight or less, 1.7 parts by weight or more and 3.5 parts by weight or less, 2 parts by weight or more and 3 parts by weight or less, 1 part by weight or more and 3 parts by weight or less, or 2 parts by weight or more and 4 parts by weight or less. When the content of the photoinitiator included in the adhesive composition for a semiconductor process is within the aforementioned range, the adhesion may be effectively reduced during photocuring without preventing the laser absorber from absorbing the excimer laser.

According to an embodiment of the present disclosure, the weight ratio of the photoinitiator and the laser absorber may be 1:0.3 to 1:1.5. Specifically, the weight ratio of the photoinitiator and the laser absorber may be 1:0.5 to 1:1.5, 1:0.5 to 1:1.3, 1:0.5 to 1:1, or 1:0.3 to 1:1. When the weight ratio of the photoinitiator and the laser absorber included in the adhesive composition for a semiconductor process is within the above range, the adhesive composition for a semiconductor process can effectively absorb an excimer laser and, at the same time, effectively reduce its adhesion after photocuring. Additionally, since the adhesive composition for a semiconductor process does not significantly change its optical transmittance even at the time of the heat treatment at an elevated temperature, it may be easily applied to a semiconductor package manufacturing process.

According to an embodiment of the present disclosure, the adhesive binder resin may comprise a (meth)acrylic copolymer that is a reaction product of a (meth)acryloyl group-containing isocyanate-based compound with a polymer of a monomer mixture comprising a (meth)acrylate-based monomer containing an alkyl group having 1 to 10 carbon atoms and a polar group-containing (meth)acrylate-based monomer.

Since the adhesive binder resin includes the (meth)acrylic copolymer, the adhesive composition for a semiconductor process can exhibit excellent adhesive properties before the photocuring.

According to an embodiment of the present disclosure, the alkyl group-containing (meth)acrylate-based monomer may include at least one selected from the group consisting of methyl (meth)acrylate, ethyl (meth)acrylate, n-propyl (meth)acrylate, isopropyl (meth)acrylate, n-butyl (meth)acrylate, isobutyl (meth)acrylate, n-pentyl (meth)acrylate, isopentyl (meth)acrylate, n-hexyl (meth)acrylate, isohexyl (meth)acrylate, n-heptyl (meth)acrylate, isoheptyl (meth)acrylate, n-octyl (meth)acrylate, isooctyl (meth)acrylate, ethylhexyl (meth)acrylate, n-nonyl (meth)acrylate, isononyl (meth)acrylate, n-decyl (meth)acrylate, and isodecyl (meth)acrylate. When a (meth)acrylate compound containing an alkyl group having a carbon number in the above-described range is used as the first (meth)acrylate-based monomer, it is possible to suppress a decrease in the physical properties of the adhesive layer.

According to an embodiment of the present disclosure, based on 100 parts by weight of the monomer mixture, the content of the alkyl group-containing (meth)acrylate-based monomer may be 60 parts by weight or more and 85 parts by weight or less, 65 parts by weight or more and 82.5 parts by weight or less, 70 parts by weight or more and 80 parts by weight or less, or 72.5 parts by weight or more and 78 parts by weight or less. When the content of the alkyl group-containing (meth)acrylate-based monomer is within the above-described range, the adhesive composition for a semiconductor process may have excellent adhesion and may have physical properties required for the substrate for a semiconductor process.

According to an embodiment of the present disclosure, the polar group-containing (meth)acrylate-based monomer may include a hydroxyl group as a polar group. The polar group-containing (meth)acrylate-based monomer may include at least one selected from the group consisting of 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 2-hydroxyethylene glycol (meth)acrylate, and 2-hydroxypropylene glycol (meth)acrylate. By using a (meth)acrylate-based monomer containing a hydroxyl group, the glass transition temperature and weight average molecular weight of the (meth)acrylic copolymer can be adjusted to implement physical properties required for the substrate for a semiconductor process.

According to an embodiment of the present disclosure, based on 100 parts by weight of the monomer mixture, the content of the polar group-containing (meth)acrylate-based monomer is 15 parts by weight or more and 40 parts by weight or less, 17.5 parts by weight or more and 35 parts by weight or less, 20 parts by weight or more and 30 parts by weight or less, or 20 parts by weight or more and 25 parts by weight or less. When the content of the polar group-containing (meth)acrylate-based monomer is within the above-described range, the adhesive composition for a semiconductor process may have excellent adhesion, and the glass transition temperature and weight average molecular weight of the (meth)acrylic copolymer may be adjusted to appropriate ranges to implement physical properties required for the substrate for a semiconductor process.

According to an embodiment of the present disclosure, the (meth)acrylic copolymer may be a reaction product of a polymer of the monomer mixture with a (meth)acryloyl group-containing isocyanate-based compound. Specifically, the (meth)acrylic copolymer may be formed through an addition reaction of the polymer with the (meth)acryloyl group-containing isocyanate-based compound. In this case, the addition reaction may mean an addition polymerization reaction, and by the addition reaction, the hydroxyl group present at the end of the polymer reacts with the isocyanate group of the (meth)acryloyl group-containing isocyanate-based compound to form a urethane bond in the side chain of the (meth)acrylic copolymer. As a urethane bond is formed in the side chain of the (meth)acrylic copolymer, mechanical properties such as shear strength of the adhesive layer including the adhesive composition for a semiconductor process can be improved, and physical properties required for the substrate for a semiconductor process can be implemented.

Additionally, in the (meth) acrylic copolymer, the (meth)acryloyl group-containing isocyanate-based compound is introduced, so the adhesive composition for a semiconductor process may more easily realize a physical property of absorbing an excimer laser and a physical property of lowering its adhesion after photocuring.

According to an embodiment of the present disclosure, the (meth)acryloyl group-containing isocyanate-based compound may include at least one of methacryloyloxyethyl isocyanate (MOI) or acryloyloxyethyl isocyanate (AOI).

According to an embodiment of the present disclosure, the content of the (meth)acryloyl group-containing isocyanate-based compound may be 65 mol % or more and 90 mol % or less with respect to 100 mol % of the polar group-containing (meth)acrylate-based monomer. Specifically, with respect to 100 mol % of the polar group-containing (meth)acrylate-based monomer used in the preparation of the polymer, the content may be 65 mol % or more and 90 mol % or less, 70 mol % or more and 90 mol % or less, 75 mol % or more and 90 mol % or less, 80 mol % or more and 90 mol % or less, or 85 mol % or more and 90 mol % or less. When the content of the (meth)acryloyl group-containing isocyanate-based compound is within the above-described range, the composition for a semiconductor process can have improved mechanical properties, and can implement physical properties required for the substrate for a semiconductor process. Also, when the content of the (meth)acryloyl group-containing isocyanate-based compound is within the above-described range, the adhesive composition for a semiconductor process can more easily implement physical properties of absorbing an excimer laser and of lowering its adhesion after photocuring, and the optical transmittance is not significantly changed even at the time of the heat treatment at an elevated temperature (e.g., 240° C.), so it can be easily applied to a semiconductor package manufacturing process.

According to an embodiment of the present disclosure, the adhesive composition for a semiconductor process may further include a curing agent. In this case, the curing agent may be a thermal-curing agent, and any thermal-curing agent used in the art may be employed without limitation. For example, an isocyanate-based curing agent may be used as the curing agent, although the type of the curing agent is not limited thereto.

According to an embodiment of the present disclosure, with respect to 100 parts by weight of the adhesive binder resin, the content of the curing agent may be 0.5 parts by weight or more and 1.5 parts by weight or less. When the content of the curing agent is within the above-described range, the adhesive composition for a semiconductor process may effectively form an adhesive layer at the time of heat treatment at a temperature of 100° C. or higher and 150° C. or lower.

According to an embodiment of the present disclosure, the adhesive composition for a semiconductor process may have an optical transmittance of 10% or less with respect to a light having a wavelength of 310 nm. Specifically, the adhesive composition for a semiconductor process has an optical transmittance of 9% or less, 8% or less, 7% or less, 6% or less, 4% or less, 3% or less, 2% or less, 1% or less, 0.5% or less, or 0.3% or less with respect to a light having a wavelength of 310 nm. In addition, the adhesive composition for a semiconductor process may have an optical transmittance of 0.1% or more, 0.3% or more, 0.5% or more, 1% or more, 2% or more, or 3% or more with respect to a light having a wavelength of 310 nm. The adhesive composition for a semiconductor process whose optical transmittance with respect to a light having a wavelength of 310 nm satisfies the above-described range may effectively absorb the excimer laser.

According to an embodiment of the present disclosure, the adhesive composition for a semiconductor process may satisfy Equation 1 below.

$$0 \leq ( T 2 - T 1 ) / T 1 \leq 0.4 \qquad [ Equation 1 ]$$

In Equation 1 above, T1 is an initial optical transmittance (%) of the adhesive composition with respect to a light having a wavelength value of 310 nm, and T2 is an optical transmittance (%) of the adhesive composition for a semiconductor process with respect to a light having a wavelength value of 310 nm after heat treatment of the adhesive composition at 240° C. for 10 minutes. Specifically, the (T2-T1)/T1 value of Equation 1 above may be 0 or more and 0.35 or less, 0 or more and 0.3 or less, 0 or more and 0.25 or less, 0 or more and 0.2 or less, 0 or more and 0.15 or less, or 0 or more and 0.1 or less. The composition for a semiconductor process satisfying Equation 1 above may be easily applied to a semiconductor package manufacturing process because it can absorb the excimer laser effectively, and its optical transmittance does not change significantly even at the time of heat treatment at an elevated temperature (e.g., 240° C.).

According to an embodiment of the present disclosure, the adhesive composition for a semiconductor process may have a degree of cure of 50% or more at the time of photocuring.

Specifically, the adhesive composition for a semiconductor process may have a degree of cure of 60% or more, or 70% or more, 90% or less, or 80% or less at the time of photocuring. After photocuring, the adhesive composition for a semiconductor process having a degree of cure satisfying the above-described range may be effectively cured as light is irradiated, and thus adhesion may be more easily reduced. The degree of cure of the semiconductor adhesive composition after photocuring may be calculated through C═C (double bond between carbons) peak areas before and after light irradiation using FT-IR, as will be described later.

According to an embodiment of the present disclosure, the adhesive composition for a semiconductor process may have an adhesion of 20 gf/in or more before photocuring. Specifically, the adhesion of the adhesive layer to the wafer is 20 gf/in or more, 40 gf/in or more, 60 gf/in or more, 70 gf/in or more, or 80 gf/in or more, wherein the adhesive layer includes the photocured material of the adhesive composition for a semiconductor process. The adhesion of the adhesive layer to the wafer is also 200 gf/in or less, 180 gf/in or less, 160 gf/in or less, 140 gf/in or less, or 120 gf/in or less, wherein the adhesive layer includes the photocured material of the adhesive composition for a semiconductor process. The film for a semiconductor process including an adhesive layer having the adhesive composition for a semiconductor process whose adhesion before photocuring satisfies the above-mentioned range can reliably fix a wafer during a semiconductor process, and can prevent the occurrence of a chip flying phenomenon in which the semiconductor chip flies and a chipping phenomenon in which the edge of the semiconductor chip is chipped.

According to an embodiment of the present disclosure, the adhesive composition for a semiconductor process may have an adhesion of 30 gf/in or less after photocuring. Specifically, the adhesion of the adhesive layer to the wafer is 30 gf/in or less, 20 gf/in or less, 10 gf/in or less, 7.5 gf/in or less, 5 gf/in or less, or 3.5 gf/in or less wherein the adhesive layer includes the photocured material of the adhesive composition for a semiconductor process. In addition, the adhesive composition for a semiconductor process may have an adhesion of 2 gf/in or more, 2.5 gf/in or more, 3 gf/in or more, or 4 gf/in or more after photocuring. The adhesive composition for a semiconductor process, which has an adhesion after photocuring satisfies the above-described range, can easily implement physical properties required for a film for a semiconductor process used in a method for manufacturing a semiconductor package to be described later.

In order to measure the adhesion after photo-curing of the adhesive composition for a semiconductor process, UV having a wavelength range of 200 nm to 400 nm may be irradiated under conditions of 2,000 mJ to 4,000 mJ with respect to the adhesive composition for a semiconductor process.

According to an embodiment of the present disclosure, the adhesive composition for a semiconductor process may satisfy Equation 2 below.

$$0.5 \leq ( A 1 - A 2 ) / A 1 \leq 0.99 \qquad [ Equation 2 ]$$

In Equation 2 above, A1 is the initial adhesion (gf/in) of the adhesive composition for a semiconductor process, and A2 is the adhesion (gf/in) of the adhesive composition for a semiconductor process after photocuring. Specifically, the (A1-A2)/A1 value of Equation 2 above may be 0.5 or more and 0.99 or less, 0.6 or more and 0.99 or less, 0.7 or more and 0.99 or less, 0.8 or more and 0.99 or less, 0.9 or more and 0.99 or less, or 0.95 or more and 0.99 or less. The composition for a semiconductor process satisfying Equation 2 above effectively lowers its adhesion after photocuring compared to that before photocuring, so that the film for a semiconductor process used in the method for manufacturing a semiconductor package to be described later can easily implement required physical properties.

An embodiment of the present disclosure provides a film for a semiconductor process including a substrate; and an adhesive layer having said adhesive composition for a semiconductor process.

The film for a semiconductor process according to an embodiment of the present disclosure effectively absorbs a laser irradiated at the time of the debonding process of the wafer carrier, and effectively reduces its adhesion after the light irradiation, so that it can be easily delaminated from the wafer.

According to an embodiment of the present disclosure, the film for a semiconductor process may include a release film, and the substrate, the adhesive layer, and the release film may be sequentially laminated in this order. The release film may serve to protect the adhesive layer of the film for a semiconductor process. The release film may be peeled off before the adhesive layer is attached to the surface of the wafer.

According to an embodiment of the present disclosure, the adhesive layer may include the adhesive composition for a semiconductor process according to the above-described embodiments. Specifically, the adhesive layer may include a thermally cured material (or dried material) of the adhesive composition for a semiconductor process. That is, a liquid adhesive composition for a semiconductor process is applied on the substrate, and then heat-treated at a temperature of 100° C. or higher and 150° C. or lower for 3 to 10 minutes to form an adhesive layer in the form of a film.

According to an embodiment of the present disclosure, the thickness of the adhesive layer may be 25 μm or more. Specifically, the thickness of the adhesive layer may be 25 μm or more and 50 μm or less, 27 μm or more and 48 μm or less, 30 μm or more and 45 μm or less, 30 μm or more and 42 μm or less, 30 μm or more and 40 μm or less, or 25 μm or more and 35 μm or less. When the thickness of the adhesive layer is within the above-described range, the film for a semiconductor process may be stably adhered to the semiconductor wafer, and excellent adhesion reliability may be realized during the processing process of the wafer.

According to an embodiment of the present disclosure, the substrate may be a polyethylene terephthalate film, polyolefin film, PEN (polyethylene naphthalate) film, ethylene-vinyl acetate film, polybutylene terephthalate film, polypropylene film or polyethylene film, but the kind of the substrate is not limited thereto.

According to an embodiment of the present disclosure, the thickness of the substrate may be 10 μm or more and 100 μm or less. Specifically, the thickness of the substrate may be 20 μm or more and 80 μm or less, 40 μm or more and 60 μm or less, 10 μm or more and 70 μm or less, 15 μm or more and 65 μm or less, 25 μm or more and 62.5 μm or less, 30 μm or more and 57 μm or less, 35 μm or more and 55 μm or less, 45 μm or more and 50 μm or less, 40 μm or more and 100 μm or less, 42.5 μm or more and 75 μm or less, 45 μm or more and 72.5 μm or less, or 50 μm or more and 65 μm or less. When the thickness of the substrate is within the above-described range, it is possible to implement the film for a semiconductor process having excellent mechanical properties.

An embodiment of the present disclosure provides a method for manufacturing a semiconductor package, the method comprising: preparing a wafer stack comprising a wafer and a carrier provided on one surface of the wafer; attaching the adhesive layer of the film for a semiconductor process on the other surface of the wafer; delaminating the carrier from the one surface of the wafer by irradiating a laser to the wafer stack; processing the wafer; and delaminating the film for a semiconductor process from the other surface of the wafer after curing the adhesive layer by irradiating a light on the adhesive layer.

The method for manufacturing a semiconductor package according to an embodiment of the present disclosure enables the carrier to be easily delaminated using an excimer laser after processing a wafer, and enables the film for a semiconductor process to be effectively delaminated through light irradiation, thereby effectively improving the semiconductor package manufacture efficiency.

According to an embodiment of the present disclosure, the wafer may be a non-pre-processed silicon wafer as it is, or a pre-processed wafer. For example, the pre-processed wafer may be a device wafer which has a surface provided with a functional coating thereon, or a device wafer on which wirings, bumps, and the like are formed. However, the kind of the wafer is not limited to the above, but any wafer used in the art may be applied without limitation.

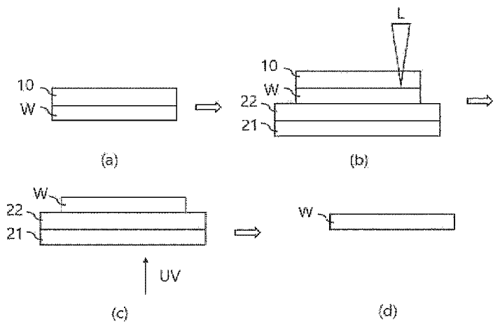

FIG. 1 is a diagram schematically showing a method for manufacturing a semiconductor package according to an embodiment of the present disclosure.

Referring to (a) of FIG. 1, a wafer stack may be prepared by providing a carrier 10 on one surface of a wafer W. In this regard, the carrier may be a wafer carrier, which includes, without limitation to, any wafer carrier used in the art. For example, glass, silicon, silicon nitride, or quartz may be used as the carrier.

Referring to (b) of FIG. 1, an adhesive layer 22 of a film for a semiconductor process according to the above-described embodiment may be laminated to be attached to the other surface of the wafer W. Thereafter, a laser L may be irradiated in a direction from the carrier 10 to a substrate 21 of the film for a semiconductor process. In this case, the laser may be the above-described excimer laser. Meanwhile, as described above, the adhesive layer including the adhesive composition absorbs the laser as it contains a laser absorber, thereby effectively preventing the laser from reaching the substrate. Through this, it is possible to effectively suppress the deformation or damage of the substrate in the debonding (delamination) process of the carrier, thereby effectively maintaining excellent adhesion reliability of the film for a semiconductor process to the wafer.

Referring to (c) of FIG. 1, after irradiating the laser L, the carrier 10 can be delaminated (debonded) from the one surface of the wafer W. Thereafter, the semiconductor wafer may be processed through a method generally used in the art. After the processing of the semiconductor wafer has been completed, a light may be irradiated in a direction from the substrate toward the wafer. In this case, the light, which is an ultraviolet (UV) light having a wavelength range of 200 nm to 400 nm, may be irradiated under a condition of 2,000 mJ to 4,000 mJ. As the light is irradiated, the adhesive layer can be photocured, thereby significantly reducing its adhesion.

Referring to (d) of FIG. 1, by delaminating (debonding) the adhesive layer 22 with the reduced adhesion from the other surface of the wafer W, a processed semiconductor wafer can be obtained.

Hereinafter, the present disclosure will be described in detail with reference to examples. However, it should be noted that the examples according to the present disclosure may be modified in various other forms, and the scope of the present disclosure is not construed as being limited to the examples to be described below. The examples of the present specification are provided to more completely explain the present disclosure to those of ordinary skill in the art.

### EXAMPLES

Hereinafter, the present disclosure will be described in detail with reference to examples.

### Example 1

### Preparing an Adhesive Binder Resin

A mixture of monomers consisting of 76.35 g of 2-ethylhexyl acrylate (2-EHA) and 23.65 g of hydroxyethyl acrylate (HEA) was put into a reactor in which nitrogen gas was refluxed and a cooling device was installed to facilitate temperature control. Then, 200 g of ethyl acetate (EAc) as a solvent was added based on 100 g of the monomer mixture, and this mixture was sufficiently mixed at 30° C. for 30 minutes or more while injecting nitrogen into the reactor in order to remove oxygen therefrom. Thereafter, the temperature was increased and maintained at 65° C., 0.1 g of a reaction initiator V-60 (Azobisisobutyronitrile) was dividedly added, and the reaction was started, followed by polymerization for 6 hours to prepare a primary reactant (polymer).

After mixing 26.88 g of 2-methacroyloxyethyl isocyanate (MOI) (85 mol % with respect to HEA in the primary reactant) and 0.27 g of a catalyst (DBTDL: dibutyltin dilaurate) to the primary reactant, an ultraviolet curing group was introduced to the polymer side chain in the primary reactant by reacting at 40° C. for 24 hours, so that a (meth)acrylate-based copolymer (adhesive binder resin) having a photopolymerizable side chain was prepared. At this time, the weight average molecular weight of the prepared (meth)acrylate-based copolymer (adhesive binder resin) was about 700,000 g/mol.

### Preparing an Adhesive Composition for a Semiconductor Process

Irgacure 819 (IGM Resins Company) was prepared as a photoinitiator, and 2-(4,6-diphenyl-1,3,5-triazin-2-yl)-5-[2-(2-ethylhexanoyloxy)ethoxy]-phenol (manufactured by ADEKA, LA 46) as a triazine-based compound was prepared as a laser absorber, and AK-75 as an isocyanate-based curing agent was prepared as a curing agent.

Thereafter, with respect to 100 parts by weight of the (meth)acrylate-based copolymer prepared above, 2 parts by weight of a photoinitiator, 1 part by weight of a laser absorber, and 0.95 parts by weight of a curing agent were mixed to prepare an adhesive composition for a semiconductor process.

### Preparing a Film for a Semiconductor Process

The adhesive composition for a semiconductor process prepared above was diluted with methyl ethyl ketone (MEK) as a solvent to have a viscosity (about 1,000 cp) suitable for coating, and mixed for 15 minutes using a stirrer. After leaving the adhesive composition for a semiconductor process at room temperature to remove the bubbles generated during mixing, and applying it on a release-treated polyethylene terephthalate film (thickness 38 μm) using an applicator, by drying the film at 110° C. for 4 minutes using an oven (Mathis), an adhesive layer with a thickness of about 30 μm was formed. After that, the adhesive layer was laminated on the corona-treated surface of a PEN film (Q65H, Toyobo Company) having a thickness of 50 μm as a substrate, and was aged at 40° C. for 3 days to prepare a film for a semiconductor process.

### Example 2

The (meth)acrylate-based copolymer (adhesive binder resin) prepared in Example 1 was prepared. Thereafter, an adhesive composition for a semiconductor process and a film for a semiconductor process were prepared in the same manner as in Example 1, except that Tinuvin 1600 (manufactured by BASF) as a triazine-based compound was used as a laser absorber.

### Example 3

The (meth)acrylate-based copolymer (adhesive binder resin) prepared in Example 1 was prepared. Thereafter, an adhesive composition for a semiconductor process and a film for a semiconductor process were prepared in the same manner as in Example 1, except that Uvinul 3030 (manufactured by BASF) as a cyanoacrylate-based compound was used as a laser absorber.

### Example 4

An adhesive composition for a semiconductor process and a film for a semiconductor process were prepared in the same manner as in Example 3, except that the content of the laser absorber was adjusted to 2 parts by weight based on 100 parts by weight of the adhesive binder resin in Example 3 above.

### Example 5

An adhesive composition for a semiconductor process and a film for a semiconductor process were prepared in the same manner as in Example 3, except that Omnirad 907 (IGM Resins Company) was used as a photoinitiator and a PET film (TOR, SKC Company) having a thickness of 50 μm was used as a substrate, in Example 3 above.

TABLE 1

| | Adhesive composition for | | | | |
|---|---|---|---|---|---|
| | semiconductor process | | | | |
| | Photoinitiator | | Laser absorber | | |
| | | Content | | Content | |
| | | (parts by | | (parts by | |
| | Kind | weight) | Kind | weight) | Substrate |
| Example 1 | A1 | 2 | B1 | 1 | C1 |
| Example 2 | A1 | 2 | B2 | 1 | C1 |
| Example 3 | A1 | 2 | B3 | 1 | C1 |
| Example 4 | A1 | 2 | B3 | 2 | C1 |
| Example 5 | A2 | 2 | B3 | 1 | C2 |

In Table 1, A1 represents Irgacure 819, A2 represents Omnirad 907, B1 represents LA46, B2 represents Tinuvin 1600, B3 represents Uvinul 3030, C1 represents a PEN film, and C2 represents a PET film. In addition, in Table 1, the contents of the photoinitiator and the laser absorber are ones (parts by weight) based on 100 parts by weight of the (meth)acrylate-based copolymer (adhesive binder resin).

### Comparative Example 1

An adhesive composition for a semiconductor process and a film for a semiconductor process were prepared in the same manner as in Example 1, except that a laser absorber was not used in the preparation of the adhesive composition for a semiconductor process in Example 1.

### Comparative Example 2

An adhesive composition for a semiconductor process and a film for a semiconductor process were prepared in the same manner as in Example 1, except that SONGSORB UV-1 (Songwon Industrial Company), a benzoate-based compound, was used as a laser absorber.

### Comparative Example 3

An adhesive composition for a semiconductor process and a film for a semiconductor process were prepared in the same manner as in Example 1, except that SONGSORB CS 928 (Songwon Industrial Company), a benzotriazole-based compound, was used as a laser absorber.

### Comparative Example 4

An adhesive composition for a semiconductor process and a film for a semiconductor process were prepared in the same manner as in Example 1, except that SONGSORB CS 312 (Songwon Industrial Company), an oxanilide-based compound, was used as a laser absorber.

TABLE 2

| | Adhesive composition for | | | | |
|---|---|---|---|---|---|
| | semiconductor process | | | | |
| | Photoinitiator | | Laser absorber | | |
| | | Content | | Content | |
| | | (parts by | | (parts by | |
| | Kind | weight) | Kind | weight) | Substrate |
| Comparative | A1 | 2 | — | | C1 |
| Example 1 | | | | | |
| Comparative | A1 | 2 | B4 | 1 | C1 |
| example 2 | | | | | |
| Comparative | A1 | 2 | B5 | 1 | C1 |
| Example 3 | | | | | |
| Comparative | A1 | 2 | B6 | 2 | C1 |
| Example 4 | | | | | |

In Table 2 above, A1 represents Irgacure 819, B4 represents SONGSORB UV-1, B5 represents SONGSORB CS 928, B6 represents SONGSORB CS 312, and C1 represents PEN film. In addition, in Table 2 above, the contents of the photoinitiator and the laser absorber are amounts (parts by weight) based on 100 parts by weight of the (meth)acrylate-based copolymer (adhesive binder resin).

The adhesive composition for a semiconductor process and the film for a semiconductor process of each of Comparative Examples were prepared in the same manner as in Example 1, except that the laser absorber used in the preparation of the adhesive composition in Example 1 was not used.

### Experimental Example

### Measuring an Optical Transmittance

The optical transmittances of the adhesive layers themselves prepared in Examples 1 to 5 and Comparative Examples 1 to 4 were measured as follows.

The adhesive layer prepared by using the adhesive composition for a semiconductor process prepared in Example 1 was laminated alone on LCD Bare glass (0.5 mm thickness) to prepare a sample having a size of 50 mm×50 mm. Then, using Shimadzu-UV2500, the optical transmittance in a wavelength band between 200 nm and 800 nm was measured, followed by the confirmation of the optical transmittance numerical value at 310 nm.

On the other hand, the prepared sample was put in an oven and stored in it at 240° C. for 10 minutes, and then, using Shimadzu-UV2500, the optical transmittance in a wavelength band between 200 nm and 800 nm was measured, followed by the confirmation of the optical transmittance numerical value at 310 nm.

In addition, the optical transmittances of the adhesive layers prepared in Examples 2 to 5 and Comparative Examples 1 to 4 were measured in the same manner.

The optical transmittance before heat treatment, optical transmittance after heat treatment, and the rate of change of optical transmittance calculated through Equation 1 above are shown in Table 3 below.

### Measuring a Degree of Cure

The degrees of cure of the adhesive layers prepared in Examples 1 to 5 and Comparative Examples 1 to 4 were measured as follows.

A film for a semiconductor process having an adhesive layer prepared by using the adhesive composition for a semiconductor process prepared in Example 1 was prepared. Then, after irradiating 3,000 mJ of UV (about 350 nm to 400 nm) in the direction from the substrate of the film for a semiconductor process toward the adhesive layer, the degree of cure was measured by calculating the change in the IR peak.

Specifically, it was measured in the FT-IR ATR mode, the C═C peak area of 814 nm before and after the UV irradiation was confirmed, and the degree of cure (%) was calculated through Equation 3 below.

$$Degree of cure ( \% ) = ( 1 - ( ( C = C peak area of 814 nm after UV irradiation ) / ( C = C peak area of 814 nm before UV irradiation ) ) ) \times 100 \qquad [ Equation 3 ]$$

In addition, the degrees of cure were measured in the same manner for the adhesive layers prepared in Examples 2 to 5 and Comparative Examples 1 to 4, and the results are shown in Table 3 below.

### Measuring an Adhesion

The adhesions of the adhesive layers prepared in Examples 1 to 5 and Comparative Examples 1 to 4 to the wafer were measured as follows.

A film for a semiconductor process having an adhesive layer prepared by using the adhesive composition for a semiconductor process prepared in Example 1 was prepared. After that, the film for a semiconductor process was cut to a size of 1 inch×25 cm, and the adhesive layer was laminated on the wafer and left at room temperature for 1 day. Thereafter, using TA (texture analyzer), peel force (adhesion) was measured by peeling the film for a semiconductor process from the wafer at a rate of 0.3 mpm and a peeling angle of 180°.

On the other hand, the separate sample prepared above was irradiated with 3,000 mJ of UV (about 350 nm to 400 nm) in the direction from the substrate of the film for a semiconductor process to the adhesive layer. Thereafter, peel forces (adhesions) were measured in the same manner as above.

In addition, the peel forces (adhesions) of the adhesive layers prepared in Examples 2 to 5 and Comparative Examples 1 to 4 were measured in the same manner.

Peel forces (adhesions) before the UV irradiation, peel forces (adhesions) after UV irradiation, and rate of change of peel forces (adhesions) calculated through Equation 2 above are shown in Table 3 below.

### Appearance Evaluation

With respect to the films for a semiconductor process prepared in Examples 1 to 5 and Comparative Examples 1 to 4 above, appearance evaluation was performed after irradiation with an excimer laser.

A film for a semiconductor process having an adhesive layer prepared by using the adhesive composition for a semiconductor process prepared in Example 1 was prepared. Thereafter, an excimer laser having a wavelength value of 308 nm was irradiated in a direction from the adhesive layer of the film for a semiconductor process to the substrate. Thereafter, if there were bubbles, fumes, or loosening at the interface between the adhesive layer and the substrate of the film for a semiconductor process, it was evaluated as “X”, and if not, it was evaluated as “O.”

In addition, the appearance evaluation was performed on the films for a semiconductor process prepared in Examples 2 to 5 and Comparative Examples 1 to 4, and the results are shown in Table 3 below.

TABLE 3

| | Optical transmittance at 310 nm (%) | | | | Adhesion | | | |
|---|---|---|---|---|---|---|---|---|
| | | | Rate of | Degree | Before | After | Rate of | |
| | | 240° C., | change | of cure | UV cure | UV cure | change | Appearance |
| | Initial | 10 min | (Equation 1) | (%) | (gf/in) | (gf/in) | (Equation 2) | evaluation |
| Example 1 | 6.3 | 8 | 0.27 | 76.2 | 90.7 | 4 | 0.96 | ◯ |
| Example 2 | 0.1 | 0.1 | 0 | 73.5 | 98.2 | 3.4 | 0.97 | ◯ |
| Example 3 | 1.5 | 1.8 | 0.2 | 75.1 | 87.2 | 3.2 | 0.96 | ◯ |
| Example 4 | 0.1 | 0.1 | 0 | 72.8 | 94.7 | 3.8 | 0.96 | ◯ |
| Example 5 | 1.6 | 2.1 | 0.31 | 74.6 | 111.9 | 5.2 | 0.95 | ◯ |
| Comparative | 46.3 | 54.3 | 0.17 | 73.8 | 98.6 | 4.8 | 0.95 | X |
| Example 1 | | | | | | | | |
| Comparative | 0.1 | 48.4 | 483 | 73.7 | 90 | 3.8 | 0.96 | ◯ |
| example 2 | | | | | | | | |
| Comparative | 4 | 50.8 | 11.7 | 74.1 | 93 | 4.2 | 0.96 | ◯ |
| Example 3 | | | | | | | | |
| Comparative | 2.3 | 55.7 | 23.22 | 73.3 | 78 | 4.6 | 0.94 | ◯ |
| Example 4 | | | | | | | | |

Referring to Table 3, it can be seen that by using the adhesive compositions for a semiconductor process prepared in Examples 1 to 5 according to the present disclosure, it is possible to provide adhesive layers which have low initial optical transmittances at 310 nm, low optical transmittance change rates after heat treatment, excellent adhesions before UV cure, and nevertheless, significantly reduced adhesions after UV cure. Additionally, in the case of the films for a semiconductor process with adhesive layers prepared by using the adhesive compositions for a semiconductor process prepared in Examples 1 to 5, it can be seen that the appearance evaluation results after the excimer laser irradiation are excellent.

### DESCRIPTION OF REFERENCE NUMERALS

W: Wafer
10: Carrier
21: Substrate
22: Adhesive layer
L: Laser

1. An adhesive composition for a semiconductor process, the adhesive composition comprising:
an adhesive binder resin;
a photoinitiator; and
a laser absorber,
wherein the laser absorber absorbs a laser having a wavelength of 250 nm to 350 nm, and
wherein the photoinitiator is activated by a light having a wavelength different from that of the laser.

2. The adhesive composition of claim 1, wherein the laser absorber absorbs an excimer laser having a wavelength of 300 nm to 320 nm.

3. The adhesive composition of claim 1, wherein the laser absorber comprises at least one of a triazine-based compound or a cyanoacrylate-based compound.

4. The adhesive composition of claim 1, wherein a weight ratio of the photoinitiator and the laser absorber is 1:0.3 to 1:1.5.

5. The adhesive composition of claim 1, wherein a content of the laser absorber is 0.5 parts by weight or more and 3 parts by weight or less with respect to 100 parts by weight of the adhesive binder resin.

6. The adhesive composition of claim 1, wherein a content of the photoinitiator is 1 part by weight or more and 5 parts by weight or less with respect to 100 parts by weight of the adhesive binder resin.

7. The adhesive composition of claim 1, wherein the adhesive binder resin comprises a (meth)acrylic copolymer that is a reaction product of a (meth)acryloyl group-containing isocyanate-based compound with a polymer of a monomer mixture comprising a C1-C10 alkyl group-containing (meth)acrylate-based monomer and a polar group-containing (meth)acrylate-based monomer.

8. The adhesive composition of claim 7, wherein a content of the C1-C10 alkyl group-containing (meth)acrylate-based monomer is 60 parts by weight or more and 85 parts by weight or less based on 100 parts by weight of the monomer mixture.

9. The adhesive composition of claim 7, wherein a content of the polar group-containing (meth)acrylate-based monomer is 15 parts by weight or more and 40 parts by weight or less with respect to 100 parts by weight of the monomer mixture.

10. The adhesive composition of claim 7, wherein a content of the (meth)acryloyl group-containing isocyanate-based compound is 65 mol % or more and 90 mol % or less with respect to 100 mol % of the polar group-containing (meth)acrylate-based monomer.

11. The adhesive composition of claim 1, wherein the adhesive composition further comprises a curing agent, wherein a content of the curing agent is 0.5 parts by weight or more and 1.5 parts by weight or less with respect to 100 parts by weight of the adhesive binder resin.

12. The adhesive composition of claim 1, wherein the adhesive composition has an optical transmittance of 10% or less with respect to a light having a wavelength of 310 nm.

13. The adhesive composition of claim 1, wherein the adhesive composition satisfies the following -Equation 1:
$$0 \leq ( T 2 - T 1 ) / T 1 \leq 0.4 \qquad [ Equation 1 ]$$
wherein T1 is an initial optical transmittance (%) of the adhesive composition with respect to a light having a wavelength of 310 nm, and T2 is an optical transmittance (%) of the adhesive composition with respect to a light having a wavelength value of 310 nm after heat treatment of the adhesive composition at 240° C. for 10 minutes.

14. The adhesive composition of claim 1, wherein the adhesive composition has a degree of cure of 50% or more when being photocured.

15. The adhesive composition of claim 1, wherein the adhesive composition has an adhesion of 30 gf/in or less after being photocured.

16. The adhesive composition of claim 1, wherein the adhesive composition satisfies the following -Equation 2:
$$0.5 \leq ( A 1 - A 2 ) / A 1 \leq 0.99 \qquad [ Equation 2 ]$$
wherein A1 is an initial adhesion (gf/in) of the adhesive composition, and A2 is an adhesion (gf/in) of the adhesive composition after photocuring.

17. The adhesive composition of claim 1, wherein the adhesive composition has an adhesion of 20 gf/in or more before being photocured.

18. A film for a semiconductor process, the film comprising:
a substrate; and
an adhesive layer comprising the adhesive composition according to claim 1.

19. The film of claim 18, wherein the film further comprises a release film, and
wherein the substrate, the adhesive layer, and the release film are sequentially laminated.

20. A method for manufacturing a semiconductor package, the method comprising:
preparing a wafer stack comprising a wafer and a carrier provided on one surface of the wafer;
attaching the adhesive layer of the film a according to claim 18 on the other surface of the wafer;
delaminating the carrier from the one surface of the wafer by irradiating a laser to the wafer stack;
processing the wafer; and
delaminating the film from the other surface of the wafer after curing the adhesive layer by irradiating a light on the adhesive layer.
